(19) United States
(12) Patent Application Publication
(10) Pub. No.: US 2026/0251729 A1
(43) Pub. Date: Aug. 27, 2026

(54) INSPECTION DEVICE AND INSPECTION METHOD

(71) Applicant: DENSO CORPORATION, Kariya-city (JP)

(72) Inventor: Masahiro MATSUDA, Kariya-city (JP)

(21) Appl. No.: 19/653,525

(22) Filed: Apr. 21, 2026

Related U.S. Application Data
(63) Continuation of application No. PCT/JP2024/036848, filed on Oct. 16, 2024.

(30) Foreign Application Priority Data
Oct. 26, 2023 (JP) 2023-184260

(51) Int. Cl. G01R 31/64; G01R 31/72

(52) U.S. Cl. CPC G01R 31/64; G01R 31/72

(57) ABSTRACT

An inspection device comprises: a power supply circuit including a power switch that switches a power supply state to an inspection target; a reception circuit that receives a signal from the inspection target; a controller configured to acquire, in a predetermined period, a voltage value at a predetermined position of the power supply circuit or the reception circuit; control an on-off state of the power switch; and detect an abnormality of the inspection target based on data of the voltage value in the period.

### CROSS REFERENCE TO RELATED APPLICATIONS

The present application is a continuation application of International Patent Application No. PCT/JP 2024/036848 filed on Oct. 16, 2024, which designated the U.S. and claims the benefit of priority from Japanese Patent Application No. 2023-184260 filed on Oct. 26, 2023. The entire disclosures of all of the above applications are incorporated herein by reference.

### TECHNICAL FIELD

The present disclosure relates to a technology for detecting an abnormality of an inspection target connected via a cable.

### BACKGROUND

A device including an input port to which an analog signal line is connected, a first switch provided between the input port and a power supply, and a second switch provided between the input port and a ground is known as a comparative example. In a configuration of this device, the presence or absence of a disconnection is determined based on a pre-diagnosis voltage observed under a predetermined first condition and a determination voltage observed under a second condition. The pre-diagnosis voltage is a voltage of the input port in a state where the first switch and the second switch are opened. The determination voltage is a voltage of the input port at a time when a second time has elapsed after setting both of the switches to an open state after closing either one of the first switch and the second switch continuously for a predetermined first time.

### SUMMARY

According to an aspect of the present disclosure, an inspection device may include: a power supply circuit including a power switch that may switch a power supply state to an inspection target; a reception circuit that may receive a signal from the inspection target; a controller that may acquire, in a predetermined period, a voltage value at a predetermined position of the power supply circuit or the reception circuit; control an on-off state of the power switch; and detect an abnormality of the inspection target based on data of the voltage value in the period.

### BRIEF DESCRIPTION OF DRAWINGS

FIG. 1 is a diagram showing an overall configuration of a system.

FIG. 2 is a functional block diagram of a controller.

FIG. 3 is a diagram showing determination data.

FIG. 4 is a diagram showing an example of a configuration of a power supply circuit.

FIG. 5 is a diagram showing an example of a configuration of an input circuit.

FIG. 6 is a diagram showing an example of a configuration of an internal circuit of a door handle module.

FIG. 7 is a diagram showing a transition of an observation point voltage accompanying turning on of a power switch in a case where the door handle module is normally connected to a digital key ECU.

FIG. 8 is a diagram showing a transition of the observation point voltage accompanying turning on of the power switch in a case where the door handle module is not connected to the digital key ECU.

FIG. 9 is a sequence diagram for illustrating a mutual operation of a gateway ECU and the digital key ECU.

FIG. 10 is a flowchart for illustrating an operation of the controller.

FIG. 11 is a flowchart showing another operation example of the controller.

FIG. 12 is a diagram showing another configuration example of a filter unit.

FIG. 13 is a diagram showing another configuration example of the filter unit.

FIG. 14 is a diagram showing another configuration example of the filter unit.

FIG. 15 is a diagram showing another example of the internal circuit of the door handle module.

FIG. 16 is a diagram showing a transition pattern of a voltage in a case where there is a resistance abnormality or a capacitor abnormality.

FIG. 17 is a diagram showing a transition pattern of a voltage in a case where there is an inductor abnormality.

FIG. 18 is a diagram for illustrating parameters related to a normal pattern.

FIG. 19 is a flowchart for illustrating an operation of the controller having a diagnosis function of the internal circuit.

### DETAILED DESCRIPTION

In the inspection method of the comparative example, it is necessary that switches are arranged on both an upper side (that is, a power supply side) and a lower side (that is, a ground side) of the input port. Depending on a configuration of the device, the above determination method cannot be adopted. Therefore, another inspection method is required.

As a method for the device to detect an abnormality of the inspection target, there is also a response confirmation method in which a predetermined signal is transmitted from the device toward the inspection target, and a determination is made based on whether a predetermined response signal is returned from the inspection target. Note that the abnormality of the inspection target here may include an internal defect of the inspection target and the like in addition to a case where the inspection target and the device are not normally connected.

However, a case is also assumed where the inspection target does not have a function of performing bidirectional communication with the device. For example, there may be a case where the inspection target is a sensor or the like and is configured to unilaterally transmit a signal from the inspection target toward the device. In a case where the inspection target is configured to be incapable of bidirectional communication with the device, the response confirmation method cannot be applied.

One aspect of the present disclosure provides a technology capable of detecting an abnormality of an inspection target.

According to an aspect of the present disclosure, an inspection device comprises: a power supply circuit including a power switch that switches a power supply state to an inspection target; a reception circuit that receives a signal from the inspection target; an acquisition unit configured to acquire a voltage value at a predetermined position of the power supply circuit or the reception circuit; a power supply controller configured to control an on-state and an off-state of the power switch; and a diagnosis unit configured to detect an abnormality of the inspection target. The acquisition unit is configured to acquire the voltage value in a predetermined period from a time when the power supply controller switches a state of the power switch from the off-state to the on-state. The diagnosis unit is configured to detect the abnormality of the inspection target based on data of the voltage value in the period.

Further, an inspection method of the present disclosure is an inspection method executed by an inspection device for an inspection target. The inspection device includes a power supply circuit including a power switch that switches a power supply state to the inspection target and a reception circuit that receives a signal from the inspection target. The method comprising: switching the power switch from an off-state to an on-state; acquiring a voltage value at a predetermined position of the power supply circuit or the reception circuit for a predetermined time from a time when the power switch is switched from the off-state to the on-state; storing the voltage value in a memory; and detecting an abnormality of the inspection target based on data of the voltage value stored in the memory.

In a case where a connection with the inspection target or an inside of the inspection target has no abnormality, an inrush current generated when a power supply is turned from off to on can transition in a specific pattern. Accordingly, the voltage value at the predetermined position can also transition in a specific pattern. On the other hand, in a case where an abnormality occurs in the connection with the inspection target or an internal circuit of the inspection target, the inrush current and the voltage value corresponding thereto can transition in a pattern different from a normal time. The present disclosure has been created by focusing on characteristics of a transient period when the power supply is turned from off to on. According to the above configuration, it becomes possible to determine whether an abnormality occurs in the inspection target.

Hereinafter, an embodiment of the present disclosure will be described with reference to the drawings. The present disclosure is not limited to the following embodiment. Configurations disclosed below may be implemented with various modifications within a range not departing from the gist. Various modifications may be implemented by being combined as appropriate within a range where a technical contradiction does not occur. The present disclosure also includes a configuration that is not explicitly described, which is formed by combining a plurality of modifications. In the following description, the same reference numerals may be attached to members having the same functions, and specific descriptions thereof may be omitted. Further, the same or similar names may be attached to members having the same functions, and specific descriptions thereof may be omitted. When only a part of a configuration is mentioned, descriptions described in other places may be applied to other parts.

Hereinafter, a case will be described where a digital key ECU 1 mounted on a vehicle detects an abnormality of a door handle module 2. The digital key ECU 1 corresponds to an inspection device, and the door handle module 2 corresponds to an inspection target. The ECU is an abbreviation for Electronic Control Unit and means an electronic control device. Hereinafter, the digital key ECU 1 is also described as a DK-ECU 1. The DK is an abbreviation for Digital Key.

The DK-ECU 1 is an ECU that determines a position of a communication device with respect to the vehicle by performing wireless communication with the communication device carried by a user. An authentication result and a position determination result by the digital key ECU 1 are used for vehicle control such as unlocking, locking, or turning on a vehicle power supply of the vehicle.

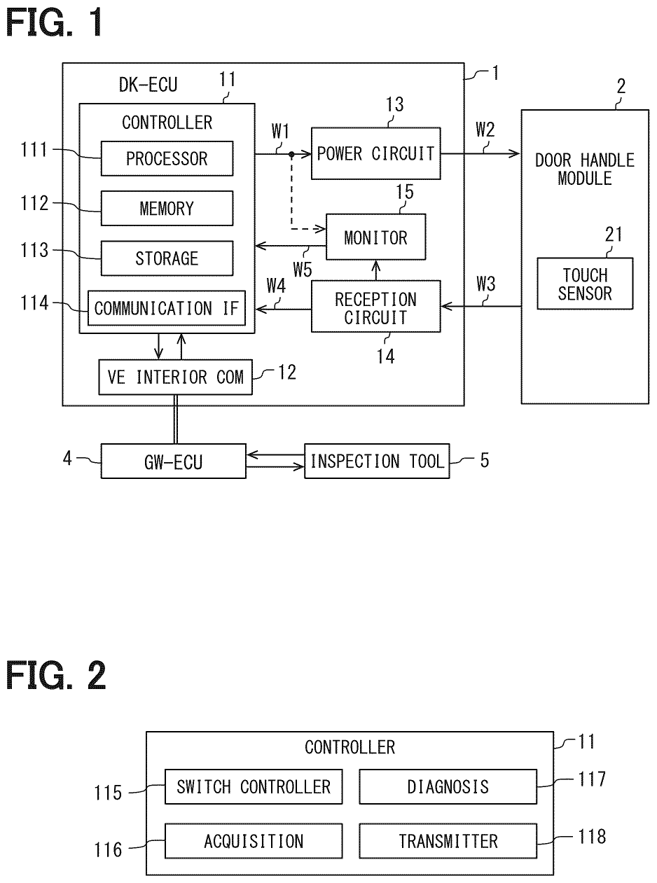

The door handle module 2 is an outer door handle itself of the vehicle, or a circuit module built in the outer door handle. The door handle module 2 includes a touch sensor 21, and is configured to output a signal indicating that the user has touched the door handle to the DK-ECU 1. The door handle module 2 can be rephrased as a touch sensor module. Hereinafter, for simplification of description, the door handle module 2 is also described as a DHM 2. The DHM is an abbreviation for Door Handle Module. Note that although only one DHM 2 is shown in FIG. 1, there may be a plurality of DHMs 2 connected to the DK-ECU 1. The DHM 2 in the following may be interpreted as any one DHM 2.

The DK-ECU 1 and the DHM 2 are connected by a power cable W2. The power cable W2 may be a cable (a so-called power cable) for supplying electric power. The power cable W2 may include a ground line W2g (for example, an outer conductor) that is a conductor connected to a ground of a power supply circuit 13, and a non-ground line W2s (for example, an inner conductor) that is a conductor connected to a non-ground side of the power supply circuit 13. Note that in a case where it is not necessary to match the ground of the power supply circuit 13 and a ground of the DHM 2, the ground line W2g is an optional element and may be omitted.

Further, the DK-ECU 1 and the DHM 2 are connected by a communication line W3. The communication line W3 is a signal line for transmitting an output (in other words, a detection result) of the touch sensor 21 to the DK-ECU 1. For example, in a case where the touch sensor 21 is touched by the user in a state where a power supply of the DHM 2 is on, the DHM 2 outputs a pulse signal rising from a low level to a high level to the communication line W3 and thus to the DK-ECU 1. Note that in a state where an activation process of the DHM 2 is completed and a touch by the user is awaited (that is, a standby state), a signal level of the communication line W3 is the low level. The low level may be interpreted as a predetermined value (for example, 0 V(volt).

The power cable W2 and the communication line W3 may be separate cables, or may be integrated into one cable. The power cable W2 and the communication line W3 may be bundled as a harness. As described above, the DHM 2 is not capable of bidirectional communication with the DK-ECU 1. In other words, the DHM 2 does not have a function of receiving an instruction from the DK-ECU 1.

### (Configuration of DK-ECU)

The DK-ECU 1 comprises a controller 11, a vehicle interior communication unit 12, the power supply circuit 13, a reception circuit 14, and a monitor unit 15. The controller 11 is configured to determine presence or absence of an abnormality of the DHM 2 based on voltage data provided from the monitor unit 15. The abnormality of the DHM 2 may include a defect of an internal circuit of the DHM 2 and the like in addition to a case where the DHM 2 and the DK-ECU 1 are not normally connected. The case where the DHM 2 and the DK-ECU 1 are not normally connected may include a case where the cable is disconnected from a connector and a case where the cable is broken.

The controller 11 may be a computer. That is, the controller 11 may include a processor 111, a memory 112, a storage 113, and a communication interface 114. The processor 111 is a configuration that performs arithmetic processing based on data received from other devices/circuits. The processor 111 may be a CPU (Central Processing Unit) or a GPU (Graphics Processing Unit) or the like. The memory 112 may be a RAM (Random Access Memory). The memory 112 may be a component for temporarily holding reception data from other devices/circuits, calculation results of the processor 111, programs, and the like. The storage 113 is a rewritable non-volatile memory. The storage 113 is implemented by, for example, at least one type of non-transitory tangible storage medium among a semiconductor memory, a magnetic medium, an optical medium, and the like. The storage 113 may include a plurality of types of storage media such as a ROM (Read Only Memory) and a flash memory. A DHM inspection program executed by the processor 111 is stored in the storage 113. Executing the DHM inspection program by the processor 111 corresponds to execution of the inspection method. The communication interface 114 is an input/output circuit for the processor 111 to receive and transmit various data.

The controller 11 comprises, as functional blocks, as shown in FIG. 2, a switch controller 115, an acquisition unit 116, a diagnosis unit 117, and a transmission unit 118. Some or all of these functional blocks may be implemented by the processor 111 executing the DHM inspection program. Of course, some functions may be implemented by an IC (Integrated Circuit), an FPGA (Field-Programmable Gate Array), or the like.

The switch controller 115 controls a connection state (on/off) of a power switch 133 included in the power supply circuit 13. The switch controller 115 corresponds to a power supply controller. The acquisition unit 116 acquires data indicating a voltage value at a predetermined observation point Pob provided in the reception circuit 14 from the monitor unit 15. Hereinafter, the voltage value of the observation point Pob is also referred to as an observation point voltage. The acquisition unit 116 temporarily saves (stores) the acquired data of the observation point voltage in the memory 112 together with a time stamp indicating an acquisition time.

As described later, the monitor unit 15 of the present embodiment is configured to detect a voltage of the observation point Pob for a predetermined sampling period from a power-on time so as to observe a transition of an inrush voltage accompanying turning on of the power supply of the DHM 2. Note that the inrush voltage here may be interpreted as a voltage fluctuation corresponding to the inrush current. The inrush voltage means a voltage higher than a steady state that is transiently generated when the power supply is switched from off to on. The above power-on time means a time when a state of the power supply of the DHM 2 is switched from an off-state to an on-state, that is, a time when the state of the power switch 133 described later is switched from the off-state to the on-state.

A length of the sampling period may be set to a value such as 2 milliseconds, 4 milliseconds, or 6 milliseconds, for example. The sampling period may be one millisecond or less such as 500 microseconds, or may be 10 milliseconds or more such as 100 milliseconds or 1 second. The length of the sampling period may be designed according to a convergence time of the DHM 2. The convergence time here may be interpreted as a time taken until a transient phenomenon accompanying the power-on converges, in other words, a required time until the internal circuit of the DHM 2 reaches a stable state. The stable state means a state where a current flowing through a circuit is a substantially constant value. The convergence time and thus the length of the sampling period may be determined based on a test or a simulation. The length of the sampling period may be determined based on observation data of a transient phenomenon in the DHM 2 in which it is confirmed that there is no internal defect.

The diagnosis unit 117 detects an abnormality of the DHM 2 based on time series data of the observation point voltage accumulated in the memory 112. Details of the diagnosis unit 117 will be described later separately. The transmission unit 118 transmits a diagnosis result of the diagnosis unit 117 to an external device. The transmission unit 118 may be configured to transmit the diagnosis result to an inspection tool 5 described later via the vehicle interior communication unit 12 and a GW-ECU 4. The expression “diagnosis” in the present disclosure may be rephrased as inspection, or detection of abnormality, or state determination. Further, detecting an abnormality may be rephrased as determining the presence or absence of an abnormality.

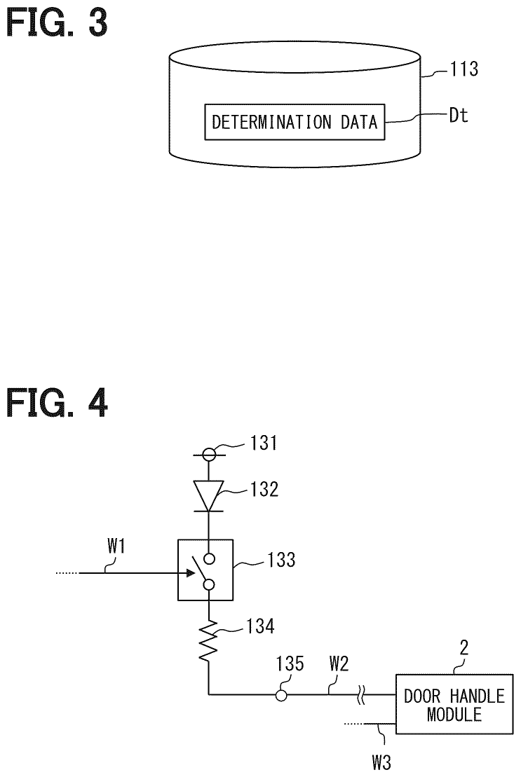

As shown in FIG. 3, determination data Dt is saved (stored) in the storage 113. The determination data Dt is data for the diagnosis unit 117 to use for diagnosis (abnormality detection) of the DHM 2. The determination data Dt is data indicating a transition of the observation point voltage observed when a predetermined reference module is properly connected to the DK-ECU 1. The reference module is a DHM 2 in which it is confirmed that there is no defect in an internal circuit. The determination data Dt may be interpreted as data indicating a feature of the observation point voltage serving as a sample or a reference in the diagnosis. The determination data Dt may be rephrased as normal pattern data or normal model data. The determination data Dt may be generated by a test using the reference module or a simulation. Contents of the determination data Dt will be described later separately.

The controller 11 is connected to the power supply circuit 13 by a switch control line W1. The switch control line W1 may be a microstrip line (a so-called pattern) formed on a circuit board. The switch control line W1 may include a jumper wire or a via. Note that in a case where the controller 11 and the power supply circuit 13 are formed on different boards, the switch control line W1 may be a communication cable. The switch control line W1 is a communication line through which a control signal for switching the on-off state of the power switch 133 described later flows.

Further, the controller 11 is connected to the reception circuit 14 by a signal line W4. The controller 11 is connected to the monitor unit 15 by a signal line W5. The signal lines W4 and W5 may also be microstrip lines or the like formed on the circuit board. In addition, the controller 11 is connected to the vehicle interior communication unit 12 so as to be capable of mutual communication.

The vehicle interior communication unit 12 is a circuit module for the controller 11 to communicate with other in-vehicle devices. The vehicle interior communication unit 12 may include a PHY chip or the like compliant with a communication standard of a vehicle interior network. The vehicle interior network is a communication network constructed in a vehicle Hv. A communication method of the vehicle interior network may be Controller Area Network (CAN, registered trademark), UART, Ethernet, or FLEXRAY (registered trademark), or the like.

The vehicle interior communication unit 12 is connected to, for example, a gateway ECU (hereinafter, GW-ECU) 4 via the vehicle interior network. The GW-ECU 4 is an ECU configured to be connectable to an external device such as the inspection tool 5 by wire or wirelessly. The inspection tool 5 is a specific inspection tool used by an inspector working at a factory or a dealer shop. The inspection tool 5 may comprise an input device and a display device as an HMI for the inspector. The inspection tool 5 accepts an instruction for inspection or the like by the inspector, and transfers the instruction to the GW-ECU 4. Further, the inspection tool 5 may have a function of displaying an inspection result received from the GW-ECU 4 on the display device.

In a state of being connected to the inspection tool 5, the GW-ECU 4 receives an inspection instruction from the inspection tool 5, and transmits an instruction command according to contents of the received inspection instruction to the DK-ECU 1. Further, the GW-ECU 4 receives data indicating the inspection result from the DK-ECU 1 and transmits the data toward the inspection tool 5. The GW-ECU 4 may be interpreted as a gateway/relay device that mediates communication between the inspection tool 5 and the DK-ECU 1. The GW-ECU 4 may be called a central gateway. The GW-ECU 4 may comprise a function of preventing unauthorized access to an in-vehicle system including the DK-ECU 1, for example, a verification function of a connected device.

The power supply circuit 13 is a circuit that generates a voltage to be supplied to the DHM 2. The power supply circuit 13 is connected to the DHM 2 by the power cable W2. An output voltage (Vout) of the power supply circuit 13 is input to the DHM 2 via the power cable W2. As shown in FIG. 4, the power supply circuit 13 comprises a power supply unit 131, a diode 132, the power switch 133, a resistance element 134, and an output terminal 135. The power supply unit 131 is a conductor to which a predetermined DC voltage (for example, 9.5 V) is applied. The power supply unit 131 may be a terminal connected to a battery arranged outside the DK-ECU 1, or a terminal connected to a power supply circuit of the DK-ECU 1 itself.

The diode 132, the power switch 133, and the resistance element 134 are connected in series to the power supply unit 131 in this order. An anode of the diode 132 is connected to the power supply unit 131, and a cathode is connected to the power switch 133.

The power switch 133 is a switch for switching supply/cutoff of electric power (that is, a power supply state) to the DHM 2. In the present embodiment, the power switch 133 is provided between the diode 132 and the resistance element 134, and is configured to switch conduction/non-conduction between these elements. The power switch 133 may be a transistor, a MOSFET, an IGBT, or the like. The power switch 133 is configured such that the on-off state is switched according to a signal input from the switch control line W1.

The resistance element 134 may be an element for suppressing generation of an overcurrent or adjusting the output voltage of the power supply circuit 13. A resistance value of the resistance element 134 may be designed as appropriate. For convenience, in the resistance element 134, a terminal connected to the power switch 133 is referred to as an upstream terminal, and a terminal on the opposite side thereof is referred to as a downstream terminal. The downstream terminal of the resistance element 134 is connected to the output terminal 135 of the power supply circuit 13 via a conductor component such as a microstrip line. The output terminal 135 is connected to the non-ground line W2s of the power cable W2. That is, the output terminal 135 is connected to the DHM 2 via the power cable W2. Therefore, an output voltage of the resistance element 134 corresponds to the output voltage of the power supply circuit 13. Note that the ground line W2g of the power cable W2 may be connected to the ground of the power supply circuit 13. The configuration of the power supply circuit 13 may be changed as appropriate. The configuration shown in FIG. 4 is an example.

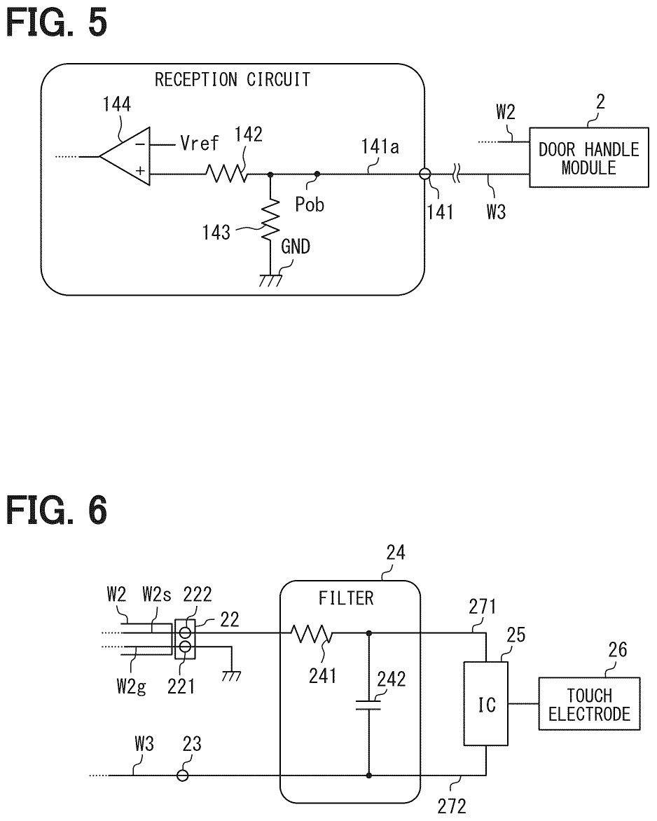

The reception circuit 14 is a circuit module to which an output signal of the DHM 2 is input via the communication line W3. The reception circuit may be rephrased as an input circuit. As shown in FIG. 5, the reception circuit 14 comprises an input terminal 141, a first resistance element 142, a second resistance element 143, and an operational amplifier 144. The input terminal 141 is a terminal to which the communication line W3 is connected. An internal signal line 141a is connected to the input terminal 141. The internal signal line 141a may be a wiring pattern (for example, a microstrip line) or the like provided on the board. One end of the internal signal line 141a is connected to the input terminal 141, and the other end is connected to the first resistance element 142. Further, the internal signal line 141a is connected to a ground (GND) of the circuit board via the second resistance element 143. The second resistance element 143 may be a configuration for maintaining an input voltage to a positive input terminal of the operational amplifier 144 at 0 V when there is no input signal or at the time of disconnection. The second resistance element 143 may play a role of adjusting an input impedance. The second resistance element 143 of the present embodiment serves as a resistor (hereinafter, a detection resistor) for detecting a magnitude of a current flowing in a transient period immediately after activation of the DHM 2. A resistance value of the second resistance element 143 may be designed as appropriate.

One end of the first resistance element 142 is connected to the input terminal 141 via the internal signal line 141a, and the other end is connected to the positive input terminal of the operational amplifier 144. A reference voltage (Vref) is input to a negative input terminal of the operational amplifier 144. The reference voltage may be designed as appropriate. With this configuration, the operational amplifier 144 amplifies and outputs an analog signal input from the input terminal 141, in other words, the output signal of the DHM 2. Various circuits such as a filter circuit and an analog-digital converter may be connected to an output side of the operational amplifier 144.

An output signal of the operational amplifier 144 is output to the signal line W4 through various circuits/as it is, and is input to the controller 11. The signal line W4 may be interpreted as a line that transmits the signal from the DHM 2 received by the reception circuit 14 to the controller 11. Similar to the switch control line W1, the signal line W4 may be a wiring pattern provided on the board.

The monitor unit 15 is a configuration that monitors a transition of an inrush current generated when the power supply of the DHM 2 is turned on. Since the current and the voltage have a proportional relationship, the monitor unit 15 may detect the magnitude of the inrush current by converting it into a voltage. The monitor unit 15 of the present embodiment is configured to detect the magnitude of the inrush current by a voltage value. In the present disclosure, a portion where the monitor unit 15 detects a voltage is referred to as an observation point Pob. In the present embodiment, the observation point Pob is set on the internal signal line 141a. That is, the monitor unit 15 of the present embodiment is configured to detect a voltage input to the reception circuit 14, in other words, an output voltage of the DHM 2. The observation point Pob corresponds to a predetermined position.

In another embodiment, the observation point Pob may be set on the output side of the operational amplifier 144. That is, the monitor unit 15 may be configured to acquire an output voltage of the operational amplifier 144. Further, the monitor unit 15 may be configured to detect a potential difference before and after the resistance element 134 included in the power supply circuit 13. This is because when a sudden current flows, a potential difference corresponding to the magnitude of the current is generated before and after the resistance element 134.

The monitor unit 15 may be a circuit that detects a voltage value (that is, an observation point voltage) at the observation point Pob. The monitor unit 15 may be implemented using an IC, a microcomputer, or an FPGA. The monitor unit 15 may be rephrased as a voltage detection circuit. Note that in another embodiment, the monitor unit 15 may be a circuit that determines whether the voltage value at the observation point Pob is equal to or larger than a predetermined threshold. For example, the monitor unit 15 may be a circuit comprising a function of determining whether the voltage value at the observation point Pob is equal to or larger than a predetermined connection threshold, whether it is equal to or larger than a peak lower limit value, and whether it is equal to or larger than a peak upper limit value. Technical meanings of the connection threshold, the peak lower limit value, and the peak upper limit value will be described later separately. In still another aspect, the monitor unit 15 may be configured to detect a current value flowing through the observation point Pob using a shunt resistor. The description of the voltage value may be replaced with the current value as appropriate.

The monitor unit 15 outputs data indicating the voltage value (that is, the observation point voltage) at the observation point Pob to the controller 11. The monitor unit 15 may be configured to execute observation of the voltage value only for the sampling period from a time when the controller 11 switches the state of the power switch 133 from the off-state to the on-state. A sampling interval which is an observation interval of the voltage value may be set to a value capable of specifying a transition of the voltage value, such as one microsecond, two microseconds, or five microseconds. The monitor unit 15 may start sampling of the voltage value based on an input of a predetermined observation start signal from the controller 11. Further, as shown by a broken line in FIG. 1, the monitor unit 15 may be configured such that the signal of the switch control line W1 is input thereto. The monitor unit 15 may be configured such that the control signal from the controller 11 to the power switch 133 is input thereto.

### (About Configuration of DHM)

As shown in FIG. 6, the DHM 2 comprises a power socket 22, an output socket 23, a filter unit 24, a touch sensor IC 25, and a touch electrode 26. The power socket 22, the output socket 23, the filter unit 24, and the touch sensor IC 25 may be arranged on a circuit board (not shown). The touch electrode 26 may be assembled to an inner surface of a housing of the DHM 2.

The power socket 22 is a socket connected to the power cable W2. The output socket 23 is a socket connected to the communication line W3. The socket may be rephrased as a jack, a receptacle, or a connector. The power socket 22 comprises a ground terminal 221 connected to the ground line W2g of the power cable W2, and a non-ground terminal 222 connected to the non-ground line W2s. The ground terminal 221 is electrically connected to a ground line (ground layer) included in the circuit board of the DHM 2. The non-ground terminal 222 is connected to the touch sensor IC 25 via the filter unit 24. Note that in a case where the power cable W2 does not comprise the ground line W2g, the ground terminal 221 may be omitted.

The filter unit 24 is a circuit for blocking/reducing power supply noise. The filter unit 24 may be an RC low-pass filter including a resistance element 241 and a capacitor 242. One end of the resistance element 241 is connected to the power socket 22, and the other end is connected to each of the capacitor 242 and the touch sensor IC 25. The capacitor 242 is arranged so as to connect a high-side signal line 271 connecting the resistance element 241 and the touch sensor IC 25, and a low-side signal line 272. That is, one end of the capacitor 242 is connected to the high-side signal line 271, and the other end is connected to the low-side signal line 272. The high-side signal line 271 corresponds to an internal signal line for supplying electric power having passed through the filter unit 24 to the touch sensor IC 25. The low-side signal line 272 is an internal signal line connecting an output terminal of the touch sensor IC 25 and the output socket 23.

The touch sensor IC 25 is an IC constituting the touch sensor 21. The touch sensor IC 25 comprises a power supply terminal (so-called Vcc), a ground terminal, and an output terminal. The power supply terminal is connected to the high-side signal line 271. The ground terminal is connected to the ground of the circuit board. The output terminal is connected to the low-side signal line 272.

The touch sensor IC 25 is also connected to the touch electrode 26. The touch electrode 26 is an electrode for the touch sensor IC 25 to detect that it has been touched by the user. The touch electrode 26 forms a different capacitance depending on whether it is touched by the user. The touch sensor IC 25 detects a touch on the door handle by the user based on a change in the capacitance of the touch electrode 26. An output signal of the touch sensor IC 25 is output to the communication line W3 via the low-side signal line 272. The touch sensor IC 25 corresponds to an integrated circuit.

A level of a voltage input from the communication line W3 to the reception circuit 14 indicates (that is, basically) presence or absence of a user touch on the touch sensor 21 when the DHM 2 is in the stable state. When the DHM 2 is in the stable state and the user is not touching, the input voltage from the communication line W3 to the reception circuit 14 is the low level (for example, 0 V). Further, when the DHM 2 is in the stable state and the user has touched, the input voltage from the communication line W3 to the reception circuit 14 temporarily becomes the high level. The input voltage from the communication line W3 to the reception circuit 14 may be rephrased as the output voltage of the DHM 2.

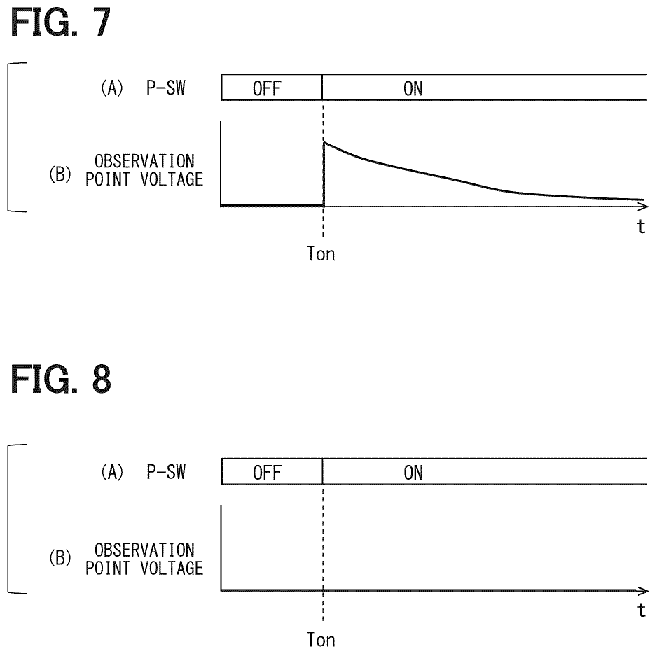

On the other hand, in a transient state immediately after turning on the power supply of the DHM 2, a voltage corresponding to the magnitude of the inrush current is input from the communication line W3 to the reception circuit 14. Therefore, in a case where the DHM 2 is connected to the DK-ECU 1, as shown in FIG. 7, a voltage level of the observation point Pob momentarily rises accompanying turning on of the power switch 133. This is due to the inrush current. Then, as a capacitor (for example, the capacitor 242) included in the internal circuit of the DHM 2 is charged, an inrush current amount attenuates. Along with this, the voltage value of the observation point Pob decreases. A state where the current no longer flows/a state where current fluctuation has converged corresponds to the stable state. Note that even in the stable state, a minute current (so-called dark current) may flow in the DHM 2 for driving the touch sensor IC 25. Therefore, the observation point voltage in the stable state can take a predetermined value larger than 0 V. In the present disclosure, the observation point voltage in the stable state is also referred to as a steady voltage. The steady voltage corresponds to the low level.

A part of (A) of FIG. 7 shows the on/off state of the power switch 133. “P-SW” in FIG. 7 means the power switch 133. A part of (B) of FIG. 7 shows the voltage of the observation point Pob, in other words, a detection value of the monitor unit 15. A horizontal axis of a graph shown in FIG. 7 represents time. Ton in FIG. 7 represents a timing when the state of the power switch 133 is switched from the off-state to the on-state. Such voltage fluctuation accompanying the power-on is similarly observed even in a case where the observation point Pob is set on the output side of the operational amplifier 144. Further, the above voltage fluctuation is due to the inrush current. Therefore, even in a case where the monitor unit 15 is configured to observe a terminal-to-terminal voltage of the resistance element 134, the above voltage fluctuation can be similarly observed.

On the other hand, in a case where the DHM 2 is not connected to the DK-ECU 1, the inrush current does not flow even if the power switch 133 is switched to on. Therefore, as shown in FIG. 8, fluctuation of the observation point voltage does not occur. The voltage value at the observation point Pob maintains the low level. In this way, the time series data of the observation point voltage when the state of the power switch 133 for the DHM 2 is switched from the off-state to the on-state can be a criterion for determining whether the DHM 2 is normally connected to the DK-ECU 1.

Note that the case where the DK-ECU 1 and the DHM 2 are not connected includes a case where the communication line W3 is disconnected from the socket of the DHM 2 or the DK-ECU 1, and a case where the communication line W3 is broken. Further, the case where the DK-ECU 1 and the DHM 2 are not connected may include a case where the power cable W2 is disconnected from the socket of the DHM 2 or the DK-ECU 1, and a case where the power cable W2 is broken. (Overall Operation)

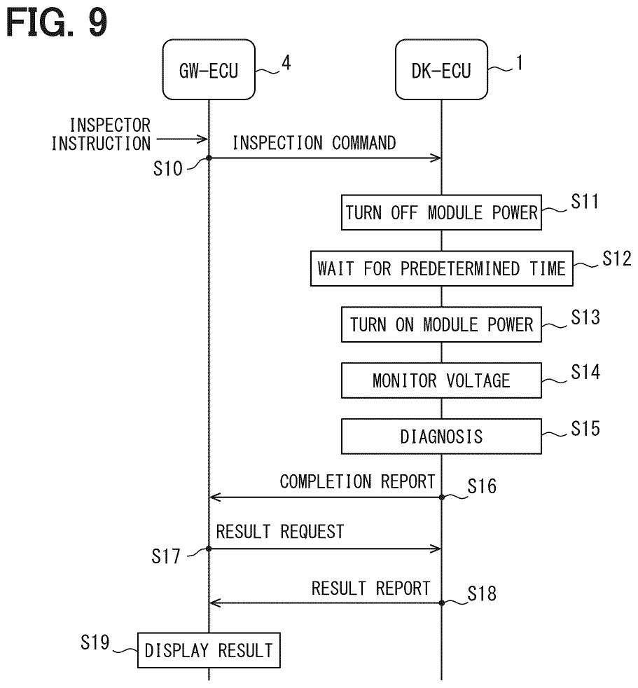

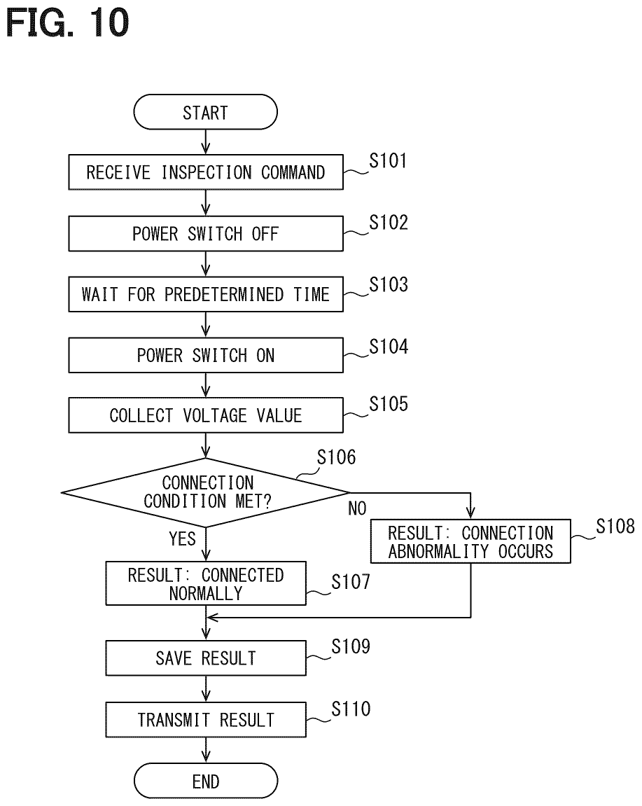

Here, an interaction between the DK-ECU 1 and the GW-ECU 4 will be described using FIG. 9 and FIG. 10. Based on acceptance of an inspection instruction by the inspector via the inspection tool 5, the GW-ECU 4 transmits an inspection command to the DK-ECU 1 (S10 in FIG. 9). The inspection command is a signal requesting the DK-ECU 1 to diagnose the DHM 2. The inspection command may be a signal including a predetermined code ordering diagnosis of the DHM 2.

Based on reception of the inspection command, the DK-ECU 1 controls the power switch 133 and sets the power supply of the DHM 2 to off (S11). Then, the off-state of the power supply is maintained for a predetermined time (hereinafter, a discharge time) (S12). S12 is a process of waiting for electric charges accumulated in a capacitor or the like of the internal circuit to be discharged. Note that in a case where the discharge time has elapsed since the power supply of the DHM 2 was turned off last time at the time of receiving the inspection command, processes in S11 to S12 may be omitted. A time when the power switch 133 was turned off last time may be saved in the memory 112 or the storage 113.

When confirming that the power-off state has been continued for the discharge time or more, the DK-ECU 1 controls the power switch 133 and turns on the power supply of the DHM 2 (S13). Further, the monitor unit 15 starts monitoring (in other words, sampling) of the observation point voltage in conjunction with turning on of the power switch 133. A period during which the monitor unit 15 monitors the observation point voltage is the sampling period described above. Note that the monitor unit 15 may be configured to execute monitoring of the observation point voltage from before the time of turning on the power supply. The monitor unit 15 may be configured to always detect the observation point voltage while the power supply of the DK-ECU 1 is in the on-state. The acquisition unit 116 may be configured to use data received within the sampling period starting from the time of turning on the power supply among observation point voltages received periodically, for the diagnosis of the DHM 2.

When the sampling by the monitor unit 15 is completed, the diagnosis unit 117 diagnoses the DHM 2 based on the sampled voltage data, that is, the time series data of the observation point voltage (S15). When the diagnosis is completed, the DK-ECU 1 saves the result and transmits a completion report toward the GW-ECU 4 (S16). Based on reception of the completion report from the DK-ECU 1, the GW-ECU 4 transmits a result request (S17). The result request may be a signal requesting transmission of the diagnosis result.

Based on reception of the result request, the DK-ECU 1 transmits a result report to the GW-ECU 4. The result report may be a signal indicating the diagnosis result. When receiving the result report, the GW-ECU 4 executes a process of displaying an image indicating the diagnosis result on a display. A display destination of the diagnosis result may be an in-vehicle display, or may be the display device of the inspection tool 5.

Note that the transmission of the completion report by the DK-ECU 1 in S16 is an optional element and may be omitted. The GW-ECU 4 may be configured to automatically transmit the result request at a timing when a certain time has elapsed from transmission of the inspection command. Further, transmission of the result request by the GW-ECU 4 is also an optional element and may be omitted. The DK-ECU 1 may be configured to transmit the result report toward the GW-ECU 4 when the diagnosis of the DHM 2 is completed.

FIG. 10 is a flowchart showing an operation of the controller 11 in the above series of operations. The description of the controller 11 below may be read as the processor 111 or the DK-ECU 1. When receiving the inspection command from the GW-ECU 4 in S101, the controller 11 sets the power switch 133 to the off-state (S102). In a case where the power switch 133 is already in the off-state at the time of receiving the inspection command, the process in S102 may be omitted. After switching the power switch 133 to the off-state, the controller 11 waits until a certain time (specifically, the discharge time) elapses (S103). In a case where the discharge time has elapsed since the power switch 133 was turned off, the controller 11 sets the power switch 133 to the on-state in S104. Note that in a case where the power switch 133 is already off at the time of receiving the inspection command, the controller 11 may execute S104 at a timing when the discharge time has elapsed since the inspection command was received. The processes in S102 to S104 correspond to the processes in S11 to S13 described above. In response to turning on the power switch 133, the monitor unit 15 starts monitoring (that is, sampling) of the observation point voltage.

In S105, the acquisition unit 116 acquires data of the observation point voltage value from the monitor unit 15, and saves the data in the memory 112 together with a time stamp/in chronological order. Then, when the sampling is completed, the diagnosis unit 117 diagnoses the DHM 2 in S106. That is, it is determined whether the time series data of the observation point voltage value satisfies a predetermined connection condition. Hereinafter, the time series data of the observation point voltage accumulated in the memory 112 is also described as observation voltage data for simplification of description.

The connection condition may be that a signal corresponding to a transient phenomenon is output from the DHM 2, that is, a voltage equal to or larger than the predetermined connection threshold is observed. In that case, the diagnosis process in S106 may be a process of determining whether a voltage equal to or larger than the predetermined connection threshold is observed. The connection threshold may be determined based on, for example, a normal peak voltage. The normal peak voltage is a maximum value of the observation point voltage observed when the reference module is connected. The connection threshold may be included in the determination data Dt. That is, the connection threshold may be saved in the storage 113 as a part of the determination data Dt.

Further, the connection condition may be that a duration for which the observation point voltage is equal to or larger than the connection threshold (hereinafter, an excess duration) in the sampling period is equal to or larger than a predetermined duration threshold. That is, processing contents in S106 may be determining whether the excess duration is equal to or larger than a predetermined value. This is because in a case where the DHM 2 is normally connected to the DK-ECU 1, the excess duration becomes equal to or larger than the predetermined value. The duration threshold may be designed in advance based on behavior in the reference module or a simulation. The duration threshold may also be included in the determination data Dt. In a case where the observation point voltage does not exceed the connection threshold, the controller 11 may regard the excess duration as 0.

In a case where the observation voltage data satisfies the connection condition (YES in S106), the diagnosis unit 117 determines in S107 that the DK-ECU 1 and the DHM 2 are normally connected. On the other hand, in a case where the observation voltage data does not satisfy the connection condition (NO in S106), the diagnosis unit 117 determines in S108 that there is an abnormality in the connection between the DK-ECU 1 and the DHM 2.

When the diagnosis (determination) related to the connection with the DHM 2 is completed, the diagnosis unit 117 stores the diagnosis result in the memory 112 in S109. Thereafter, in S110, the transmission unit 118 transmits data indicating the diagnosis result, that is, the result report toward the GW-ECU 4.

In the above configuration, a connection abnormality with the inspection target is detected according to whether a transition pattern of the voltage/current at the observation point Pob at the time of power-on is a predetermined pattern. Therefore, even if the inspection target and the inspection device are not configured to perform bidirectional communication, the connection abnormality can be detected. In addition, according to the above method/configuration, an effect of shortening inspection time can be expected. Note that the connection abnormality may be a contact failure at a connector portion or a disconnection of a cable. Inspecting a connection state with the inspection target may be called open detection or the like. The above method/configuration may be interpreted as a method/configuration for performing open detection using a transient phenomenon.

By the way, as another method for inspecting that the DHM 2 is normally connected to the DK-ECU 1, a method (hereinafter, also described as a sensor reaction confirmation method) is conceivable in which the inspector actually touches the door handle in a state where the power supply of the DHM 2 is in the on-state. In the sensor reaction confirmation method, it is determined as a connection abnormality when a pulse signal is not output from the DHM 2 in response to a handle touch by the inspector. However, in the sensor reaction confirmation method, it is necessary for a human to approach the vehicle. Therefore, if the sensor reaction confirmation method is adopted in the open inspection at a manufacturing factory, temporary stop of a machine, safety confirmation by other workers, and the like may be required. That is, in the case of the sensor reaction confirmation method, manufacturing efficiency of the vehicle may decrease. In contrast to such a sensor reaction confirmation method, according to the inspection method of the present disclosure, it is not necessary for the inspector to approach the vehicle. Therefore, it is not necessary to stop assembly work of the vehicle. The above embodiment has an advantage that the inspection of the connection state can be executed in parallel with assembly of the vehicle.

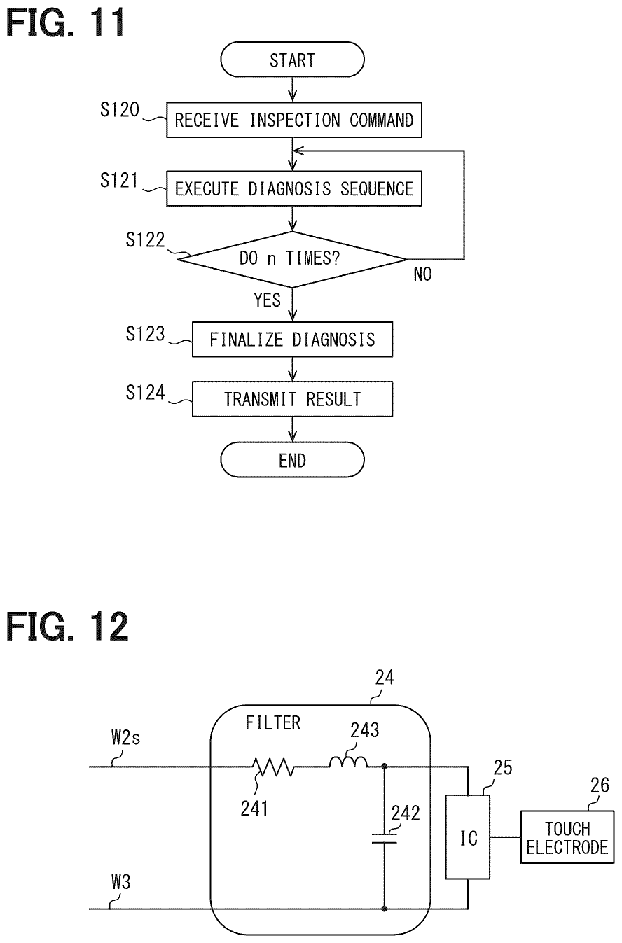

For improvement of detection accuracy, the DK-ECU 1 may execute connection diagnosis a plurality of times based on reception of the inspection command, and finally determine the connection state with the DHM 2 based on a plurality of inspection results. Hereinafter, a diagnosis result obtained by execution of one diagnosis is also referred to as a provisional diagnosis result to distinguish it from a final diagnosis result. FIG. 11 is a flowchart showing an operation of the controller 11. The flowchart shown in FIG. 11 includes processes in S120 to S124.

S120 is a process of receiving the inspection command from the GW-ECU 4. The controller 11 may be configured to execute processes after S121 based on reception of the inspection command. S121 is a process of executing a predetermined diagnosis sequence. Contents of the diagnosis sequence here may be a series of processes from processes in S102 to S109. The controller 11 acquires one provisional diagnosis result by executing the diagnosis sequence once. When executing the diagnosis sequence, in S122, the controller 11 determines whether the diagnosis sequence has been executed a predetermined number of times (n) since receiving the inspection command. The n is a parameter defining the number of repetitions of the diagnosis sequence. The n may be set to 3 or 5 or the like.

At a time when the process reaches S122, in a case where the number of executions of the diagnosis sequence is less than n times (No in S122), the controller 11 re-executes S121. That is, the controller 11 repeats the diagnosis sequence n times based on reception of the inspection command.

In a case where the diagnosis sequence is executed n times (YES in S122), the controller 11 determines the connection state of the DHM 2 based on n times of provisional diagnosis results accumulated in the memory 112 in S123. A method of determining the diagnosis result may be a majority vote. Further, in a case where a provisional diagnosis result indicating a connection abnormality is included even once in the plurality of provisional diagnosis results, the controller 11 may determine as the connection abnormality. In a case where it is determined as normal connection in all diagnosis sequences, the controller 11 may determine that the DK-ECU 1 and the DHM 2 are normally connected.

### (Circuit Configuration)

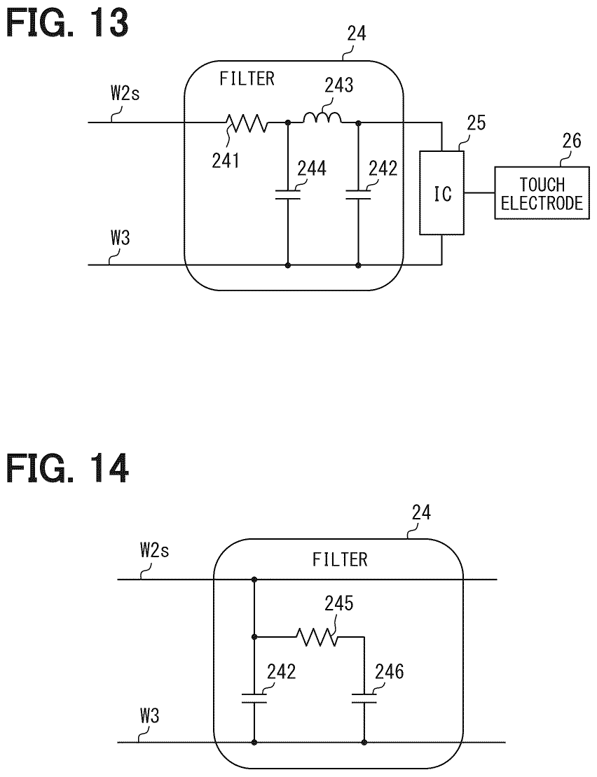

The internal circuit of the DHM 2 shown in FIG. 6 is an example and may be changed as appropriate. For example, as shown in FIG. 12, the filter unit 24 may include an inductor 243 connected in series to the resistance element 241. Further, as shown in FIG. 13, the filter unit 24 may be configured as a pi-type filter comprising a capacitor 244. As shown in FIG. 14, the filter unit 24 may have a configuration in which capacitors are connected in parallel in a stepped manner. For example, when a path passing through the capacitor 242 is defined as a first path, a second path in which a resistance element 245 and a capacitor 246 are connected in series may be connected in parallel to the capacitor 242. Further, a third path including another capacitor may be connected in parallel to the capacitor 246.

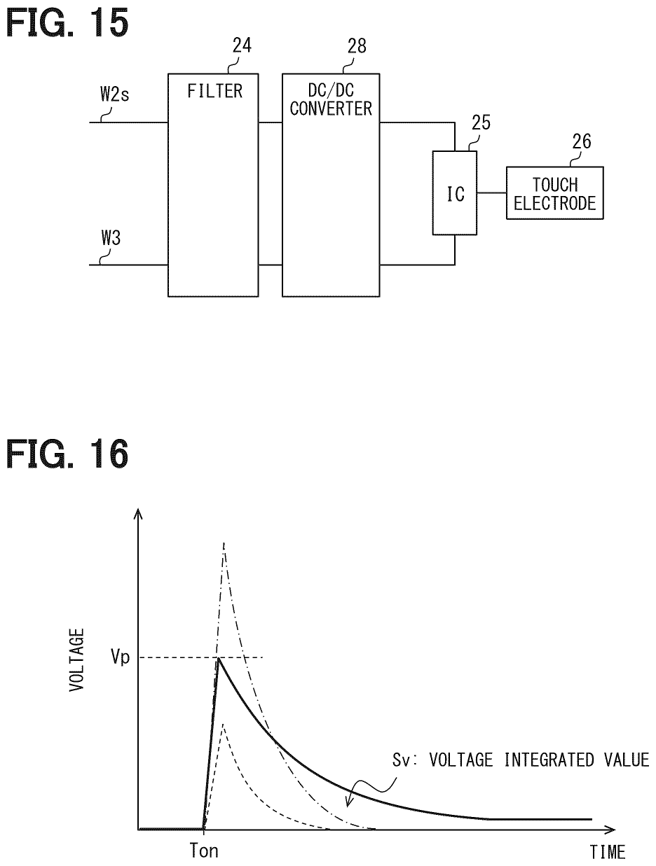

In addition, as shown in FIG. 15, a DC/DC converter 28 may be provided between the filter unit 24 and the touch sensor IC 25. The DC means direct current. The DC/DC converter 28 may be a circuit (for example, an IC) that converts a DC voltage input from the power cable W2 into another DC voltage suitable for operation of the touch sensor IC 25. The DC/DC converter 28 may be a low drop-out linear regulator (so-called LDO: Low Drop Out). The DC/DC converter 28 may be another linear regulator or switching regulator.

The transition pattern of the observation point voltage accompanying power-on can fluctuate depending on the configuration of the internal circuit. If an abnormality occurs in the resistance element, the capacitor, or the inductor included in the internal circuit, the transition pattern of the observation point voltage can be different from a normal pattern. The normal pattern here means a transition pattern of the observation point voltage that can be observed in a case where the reference module is connected to the DK-ECU 1. The transition pattern may be rephrased as a fluctuation pattern.

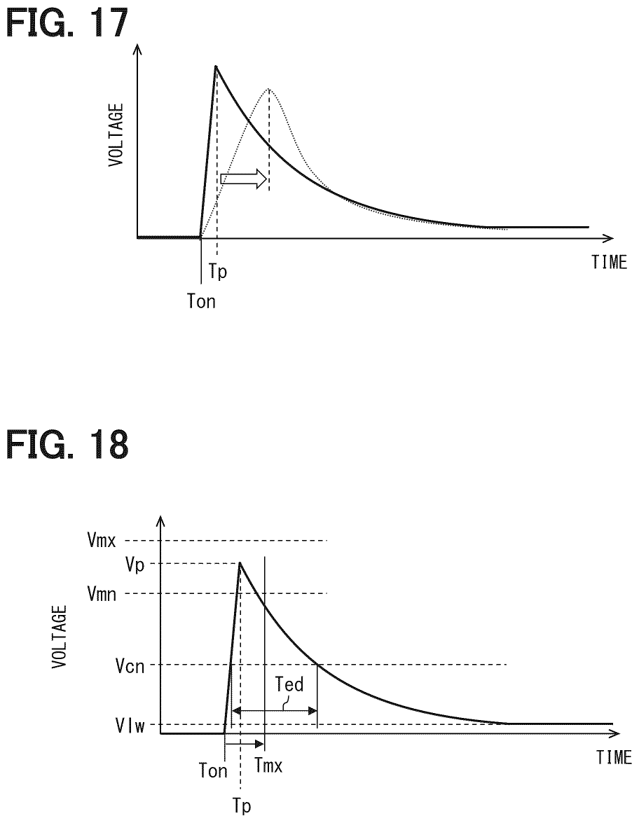

For example, in a case where the resistance element 241 of the internal circuit is short-circuited, a larger current flows through the observation point Pob than at a normal time. Therefore, as shown by a dashed-dotted line in FIG. 16, a peak value of a voltage waveform represented by the observation voltage data becomes a relatively large value. Solid lines shown in FIG. 16 and FIG. 17 represent normal patterns. A Vp shown in FIG. 16 and the like represents the peak value. The peak value in the present disclosure means a voltage value of a peak, in other words, a first local maximum value of the observation voltage data. Basically, the peak value corresponds to a maximum value in the observation voltage data. The controller 11 may regard the maximum value in the observation voltage data as the peak value. The peak value represents a position (that is, height) of the peak on a voltage axis.

Further, in a case where a capacitance (that is, capacity) of the capacitor 242 is a value smaller than a specification value, as shown by a broken line in FIG. 16, the peak value becomes smaller and an area of the voltage waveform (in other words, an integrated value of the observation point voltage) also becomes smaller compared to the normal time. This is because the integrated value of the observation point voltage is determined according to the capacity of the capacitor included in the internal circuit. The specification value here may be interpreted as a design value. Hereinafter, the integrated value of the observation point voltage is also referred to as a voltage integrated value (Sv). The voltage integrated value may be a total value of voltage values included in the observation voltage data. Note that the above abnormality of capacitance can occur due to a mistake in the capacitor 242 assembled to the board, capacitance loss, or the like. The capacitance loss can occur due to leakage of an electrolytic solution, deterioration due to secular change of the electrolytic solution, or the like.

Further, in a case where an inductance of the inductor 243 is larger than a specification value due to a mistake in parts, an arrival time of a peak (Tp) can be later than at the normal time as shown by a dotted line in FIG. 17. The Tp shown in FIG. 17 and the like represents a peak arrival time. The peak arrival time (Tp) is an elapsed time from start of observation until the peak is detected. The peak arrival time means a position of the peak in a time direction.

In addition, in a case where the filter unit 24 is a filter including an inductor and a capacitor (so-called LC filter), local maximum points of the observation point voltage can be generated at intervals of ½π√(LC) due to LC resonance. In other words, the observation voltage data can indicate a second wave or a third wave in addition to a first wave due to the LC resonance of the internal circuit. The first wave represents a wave detected first after start of observation. Unless otherwise noted, the description of peak hereinafter means a vertex (local maximum point) of the first wave, that is, a maximum value in the entire observation voltage data.

Note that the controller 11 may be configured to treat, as one wave, a state in a period from when the voltage value exceeds a predetermined value until it falls below the predetermined value. The voltage integrated value described above may be a total value of a set of voltage values corresponding to the first wave. Alternatively, the voltage integrated value may be a total value of voltage values observed from when the state of the power switch 133 is switched to the on-state until a predetermined cutoff time elapses. The cutoff time may be set so as to correspond to a time when the first wave converges. The cutoff time may be set to half of the sampling period or the like.

The peak value (Vp), the peak arrival time (Tp), and the voltage integrated value (Sv) correspond to features of the observation voltage data determined by analyzing the observation voltage data. The diagnosis unit 117 may be configured to detect an abnormality (defect) of the internal circuit based on some or all of the above features. Accordingly, the determination data Dt may include thresholds related to each of the peak value (Vp), the peak arrival time (Tp), and the voltage integrated value (Sv) as data for determining that the internal circuit is normal.

Specifically, as shown in FIG. 18, the determination data Dt may include a peak lower limit value (Vmn) defining a normal range of the peak value, and a peak upper limit value (Vmx). The peak upper limit value (Vmx) corresponds to a peak threshold and a first peak threshold. The peak lower limit value (Vmn) corresponds to a second peak threshold.

The determination data Dt may include an integral lower limit value which is a lower limit value of the voltage integrated value, and an integral upper limit value which is an upper limit value of the voltage integrated value. The integral upper limit value corresponds to an integral threshold and a first integral threshold. Further, the integral lower limit value corresponds to a second integral threshold. The integral lower limit value and the integral upper limit value are parameters defining a normal range of the voltage integrated value.

The determination data Dt may include a delay allowable time (Tmx) which is an upper limit value for the peak arrival time. The determination data Dt may include a lower limit value and an upper limit value for the above-described excess duration (Ted). The lower limit value and the upper limit value for the excess duration (Ted) are parameters defining a normal range of the excess duration (Ted). The lower limit value of the excess duration corresponds to the above-described duration threshold. A Vcn in FIG. 18 represents the connection threshold. A Vlw in FIG. 18 indicates the observation point voltage in the stable state, that is, the steady voltage.

In addition, the determination data Dt may include an upper limit value and a lower limit value of the steady voltage. The upper limit value and the lower limit value of the steady voltage are parameters defining a normal range of the steady voltage. The lower limit value of the steady voltage may be 0 V, or may be a value larger than 0 such as 0.5 V. The normal range of the steady voltage may be designed based on the normal pattern. Further, in a case where the reference module forms a plurality of waves due to LC resonance in the transient state, the determination data Dt may include an upper limit value and a lower limit value of a generation interval of local maximum points (hereinafter, a peak interval). The upper limit value and the lower limit value of the peak interval are parameters defining a normal range of the peak interval. In a case where the reference module forms a plurality of waves due to LC resonance in the transient state, the determination data Dt may include a parameter representing a normal range of the number of observations of local maximum points. The determination data Dt does not need to include all the above data. Some threshold data may be omitted.

The diagnosis unit 117 may determine that the resistance element is short-circuited in a case where the peak value included in the observation voltage data exceeds the peak upper limit value Vmx. In order to diagnose more accurately, the diagnosis unit 117 may determine that the resistance element is short-circuited in a case where the observed peak value exceeds the peak upper limit value (Vmx) and the voltage integrated value (Sv) does not exceed the integral upper limit value. The voltage integrated value is derived from the capacity of the internal circuit. Therefore, even in a case where the resistance element is short-circuited, the voltage integrated value can fall within the normal range.

Further, the diagnosis unit 117 may determine that a resistance element related abnormality or a capacitor related abnormality has occurred in a case where the peak value included in the observation voltage data falls below the peak lower limit value (Vmn). The resistance element related abnormality may include a case where the resistance value is different from the specification value due to a mistake in parts, deterioration, or the like in addition to the short circuit. In the present disclosure, the resistance element related abnormality may be also referred to as a resistance abnormality. The capacitor related abnormality means a state where the capacity of the capacitor is too large or too small with respect to the specification value. In the present disclosure, the capacitor related abnormality may be also referred to as a capacitor abnormality. The capacitor related abnormality can occur due to a mistake in parts or capacitance loss. Further, the capacitor related abnormality can also occur due to detachment of parts due to solder cracking.

The diagnosis unit 117 may be configured to determine that a capacitor related abnormality has occurred: (1) in a case where the observed peak value exceeds the peak upper limit value (Vmx) and the voltage integrated value exceeds the integral upper limit value; or (2) in a case where the peak value does not exceed the peak lower limit value (Vmn) and the voltage integrated value does not exceed the integral lower limit value. The above case (1) corresponds to a case where the capacity of the capacitor is too large with respect to the specification value. The above case (2) corresponds to a case where the capacity of the capacitor is too small with respect to the specification value.

The diagnosis unit 117 may determine that an inductor related abnormality has occurred in a case where the observed peak arrival time exceeds the delay allowable time (Tmx). This case corresponds to a case where the inductor is too large with respect to the specification value. The inductor related abnormality can also occur due to a mistake in parts or the like. In the present disclosure, the inductor related abnormality may be also referred to as an inductor abnormality.

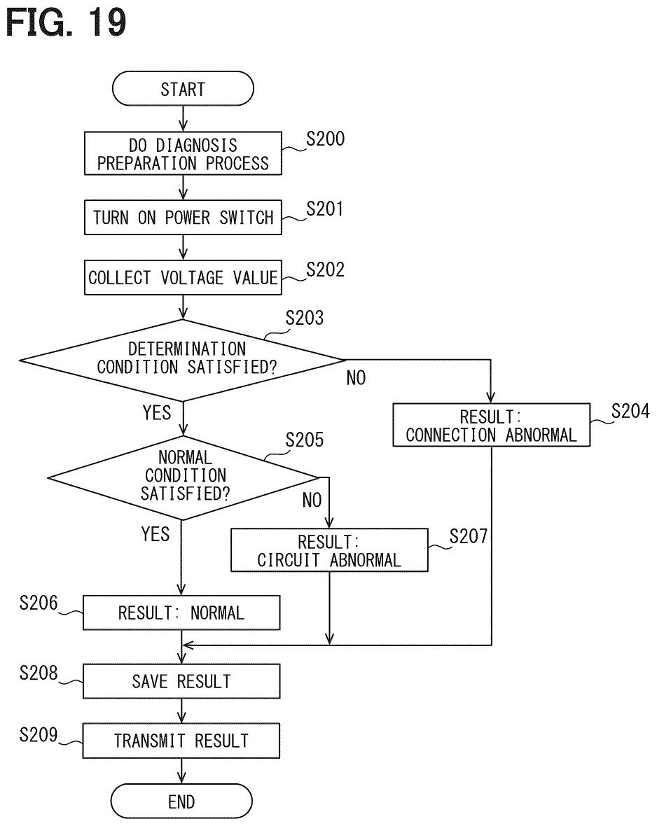

FIG. 19 is a flowchart showing an operation of the controller 11 also comprising a diagnosis function of the internal circuit in addition to the diagnosis function of the connection state. The flowchart shown in FIG. 19 includes S200 to S209.

S200 is a process of executing a diagnosis preparation process based on reception of the inspection command from the GW-ECU 4 by the controller 11. The diagnosis preparation process is a process for discharging electric charges of the internal circuit. The diagnosis preparation process may be S102 to S103 described above. When the diagnosis preparation process is completed, the controller 11 switches the state of the power switch 133 from the off-state to the on-state in S201. Then, in S202, the observation voltage data is acquired from the monitor unit 15. When acquiring the observation voltage data, the controller 11 determines whether the connection condition is satisfied in S203. S203 may be the same as S106. In a case where the observed excess duration (Ted) falls within the normal range, the controller 11 determines that the connection condition is satisfied, and executes S205. On the other hand, in a case where the excess continuation time (Ted) does not fall within the normal range, the controller 11 determines in S204 that there is an abnormality in the connection between the DK-ECU 1 and the DHM 2, and advances the process to S208.

S205 is a process of determining whether the observation voltage data satisfies a circuit normal condition. The circuit normal condition is a condition for determining that the internal circuit is normal. The circuit normal condition may be that the observed peak value, peak arrival time, and voltage integrated value respectively fall within normal ranges. In a case where the observation voltage data satisfies the circuit normal condition, that is, in a case where all of the above plurality of features fall within the normal ranges, the controller 11 determines in S206 that the internal circuit is normal, and advances the process to S208. On the other hand, in a case where the observation voltage data does not satisfy the circuit normal condition, the controller 11 determines in S207 that the abnormality has occurred in the internal circuit. The case where the observation voltage data does not satisfy the circuit normal condition may be interpreted as a case where any of the plurality of features indicated by the observation voltage data deviates from the normal range. Note that the circuit normal condition may be that a similarity between the observed transition pattern of the observation point voltage and the normal pattern is equal to or larger than a predetermined value. Calculation of the similarity may be performed by a technique such as template matching. In that case, the determination data Dt may include data necessary for calculation of the similarity, such as template data, instead of various thresholds.

In a case where determining in S207 that the circuit abnormality has occurred, the controller 11 may determine which of a resistance abnormality, a capacitor abnormality, an inductor abnormality, and unknown corresponds to a type of the abnormality by the method described above. That is, the controller 11 may be configured to determine an abnormal part based on the plurality of features determined based on the observation voltage data and the determination data Dt.

S208 is a process of saving the diagnosis result obtained by the above process in the memory 112. After execution of S208, in a case of receiving the result request from the GW-ECU 4, the controller 11 transmits the diagnosis result to the GW-ECU 4 in S209.

According to the above configuration, there is an advantage that it becomes possible to estimate whether the internal circuit of the DHM 2 is normal and the type of the circuit abnormality. Note that the controller 11 may be configured to execute the diagnosis of the internal circuit a plurality of times as well, and determine a final circuit state based on a plurality of provisional diagnosis results. That is, contents of S121 shown in FIG. 11 may be a series of processes from S200 to S208.

Note that in a case where the DHM 2 is configured to output the second wave or the third wave, the controller 11 may specify an interval at which local maximum points are observed, and determine whether it falls within the normal range of the peak interval. In a case where the generation interval of the local maximum points deviates from the normal range of the peak interval defined in the determination data Dt, the controller 11 may determine that a circuit abnormality has occurred.

Further, the determination data Dt may include the number of generations of local maximum points that should be observed in the sampling period. In a case where the number of generations of local maximum points obtained by analyzing the observation voltage data is different from the number of generations included in the determination data Dt, the controller 11 may determine that a circuit abnormality has occurred.

In addition, the controller 11 may be configured to acquire the observation point voltage after lapse of the convergence time as a detection value of the steady voltage (Vlw) from the monitor unit 15. In a case where the detection value of the steady voltage deviates from the normal range of the steady voltage included in the determination data Dt, the controller 11 may determine that a resistance abnormality has occurred.

Furthermore, the sampling period may be set so as to include a time zone during which the touch sensor IC 25 can execute the activation process (hereinafter, an IC activation period). Even while the touch sensor IC 25 is executing the activation process, the input voltage from the communication line W3 to the reception circuit 14 can fluctuate dynamically. The activation process of the touch sensor IC 25 may include initialization of a RAM and a register, activation of software, and the like. Since electric power is used for the activation process, the output voltage of the DHM 2 can fluctuate even during execution of the activation process. That is, even in the IC activation period, the observation point voltage can fluctuate in a predetermined pattern. The determination data Dt may include data defining a normal range of the observation point voltage in the IC activation period. In a case where the observation point voltage in the IC activation period exceeds the normal range or in a case where voltage fluctuation does not converge even after the IC activation period is completed, the controller 11 may determine that an abnormality has occurred in the touch sensor IC 25.

Note that by adjusting a time for maintaining the power-off, the controller 11 can remove an influence of an internal circuit such as an LDO, and can increase accuracy of diagnosis. Further, by adjusting the time for maintaining the off-state, it becomes possible to acquire a change pattern of the observation point voltage accompanying restart according to the off-state time. The controller 11 may use the change pattern of the observation point voltage accompanying restart according to the off-state time as a material for abnormality determination of the internal circuit.

### (Modifications)

The DK-ECU 1 may be configured to receive the inspection command directly from the inspection tool 5 without passing through the GW-ECU 4. Further, the DK-ECU 1 may be configured to accept the inspection instruction of the user via an in-vehicle HMI. According to this configuration, after factory shipment, the user can execute diagnosis of the DHM 2 by himself/herself.

The number of ECUs provided in the vehicle and functions in charge can be designed as appropriate. The DK-ECU 1 may be subdivided into a plurality of units. That is, another ECU may comprise some functions of the DK-ECU 1. Functional arrangement may be changed as appropriate.

In the above, the case has been described where the DK-ECU 1 determines an abnormality of the DHM 2, but a combination of the inspection device and the inspection target may be changed as appropriate. The inspection target may be other than the DHM 2. For example, the inspection target may be a rain sensor, an illuminance sensor, or a foot sensor. The foot sensor means an ultrasonic sensor or a radar for detecting that the user holds his/her foot under a door of the vehicle. The inspection target may be a device capable of bidirectional communication with the inspection device.

In the above, the inspection target and the inspection device do not necessarily have to be separate bodies, and the above inspection method may be applied to self-diagnosis of an ECU or the like. The above inspection method may be applied to inspection of whether an unintended part is attached to an ECU, and symptom diagnosis of deterioration/failure. The present disclosure is applicable to other than inspection of parts assembled to a vehicle. For example, the inspection target may be a human sensor or the like installed in a home or the like.

All of the various flowcharts shown in the present disclosure are examples, and the number of processes constituting the flowchart and an execution order of processes can be changed as appropriate. Controls shown in each flowchart may be combined/executed in parallel within a consistent range. Expressions such as acquire, determine, detect, generate, and calculate may be rephrased mutually. Acquiring certain data by a certain device also includes generating the data by the device based on a signal input from another device/sensor. Controlling the on-off state of a switch may include switching the switch from the off-state to the on-state and switching it from the on-state to the off-state. The on-state of the switch is a state where the switch is closed, and may be interpreted as a conduction state or a closed state. The off-state of the switch is a state where the switch is opened, and may be interpreted as a cutoff state, a disconnected state, or an open state.

The device, system, and method thereof described in the present disclosure may be implemented by a dedicated computer constituting a processor programmed to execute one or a plurality of functions embodied by a computer program. The device and method thereof described in the present disclosure may be implemented using a dedicated hardware logic circuit. The device and method thereof described in the present disclosure may be implemented by one or more dedicated computers configured by a combination of a processor executing a computer program and one or more hardware logic circuits. The processor may be any arithmetic core such as a CPU, an MPU, a GPU, or a DFP (Data Flow Processor). Some or all of functions included in the inspection device may be implemented as hardware. Some or all of functions included in the inspection device may be implemented using any of a system-on-chip (SoC), an IC, and an FPGA.

The computer program includes instructions executed by a computer. The computer program may be stored in a computer-readable non-transitory tangible storage medium. A recording medium of the computer program may be various media such as an HDD (Hard-disk Drive), an SSD (Solid State Drive), and a flash memory.

What is claimed is:

1. An inspection device comprising:
a power supply circuit including a power switch that switches a power supply state to an inspection target;
a reception circuit that receives a signal from the inspection target;
a controller configured to
acquire a voltage value at a predetermined position of the power supply circuit or the reception circuit;
control an on-state and an off-state of the power switch; and
detect an abnormality of the inspection target,
wherein
the controller is configured to acquire the voltage value in a predetermined period from a time when the controller switches a state of the power switch from the off-state to the on-state, and
the controller is configured to detect the abnormality of the inspection target based on data of the voltage value in the predetermined period.

2. The inspection device according to claim 1, wherein
the controller is configured to determine whether the inspection target is connected for determining the abnormality of the inspection target.

3. The inspection device according to claim 2, wherein
the controller is configured to:
determine that the inspection target is connected when a duration of a state where a voltage value exceeds a threshold in the predetermined period is equal to or larger than a predetermined value; and
determine that the inspection target is not connected when the duration of the state where the voltage value exceeds the threshold in the predetermined period is less than the predetermined value.

4. The inspection device according to claim 1, wherein
the controller is configured to determine a state of an internal circuit of the inspection target as the abnormality of the inspection target.

5. The inspection device according to claim 1, wherein
the controller is configured to detect an abnormality of an internal circuit of the inspection target based on time series data of the voltage value observed in the predetermined period.

6. The inspection device according to claim 1, wherein
the controller is configured to:
acquire an integrated value of the voltage value and a peak value of the voltage value observed in the predetermined period based on time series data of the voltage value observed in the predetermined period; and
detect an abnormality of an internal circuit of the inspection target based on the integrated value and the peak value.

7. The inspection device according to claim 6, wherein
the controller is configured to determine that a resistance element related abnormality has occurred when the peak value exceeds a peak threshold which is a threshold for the peak value, and the integrated value does not exceed an integral threshold which is a threshold for the integrated value.

8. The inspection device according to claim 6, wherein
the controller is configured to determine that a capacitor related abnormality has occurred
when the peak value exceeds a first peak threshold which is a threshold for the peak value and also the integrated value exceeds a first integral threshold which is a threshold for the integrated value or
when the peak value is smaller than a second peak threshold which is a threshold smaller than the first peak threshold and also the integrated value is smaller than a second integral threshold which is a threshold smaller than the first integral threshold.

9. The inspection device according to claim 6, wherein
the controller is configured to:
specify a peak arrival time which is a time from when the power switch is turned on until the peak value is observed based on time series data of the voltage value observed in the predetermined period; and
determine whether an inductor related abnormality has occurred based on the peak arrival time.

10. The inspection device according to claim 1, wherein
the inspection target is a device including a filter circuit including an inductor and a capacitor,
the controller is configured to:
specify a numerical number of times a plurality of local maximum points of the voltage value has been observed in the predetermined period or an observation interval of the plurality of local maximum points of the voltage value based on time series data of the voltage value observed in the predetermined period; and
detect an abnormality of the filter circuit based on the numerical number of times the plurality of local maximum points has been observed or the observation interval.

11. The inspection device according to claim 1, wherein
the inspection target includes an integrated circuit or a resistance element,
the controller acquires the voltage value after a predetermined convergence time has elapsed since the power switch switched from the off-state to the on-state, and
the controller is configured to detect an abnormality of the integrated circuit or the resistance element based on the voltage value after the predetermined convergence time has elapsed.

12. The inspection device according to claim 1, wherein
the inspection device is configured as an electronic control unit used in a vehicle,
the inspection target is a touch sensor module accommodated in a door handle, which does not include a bidirectional communication function with another device, and
the reception circuit is a circuit that receives an output signal from the touch sensor module.

13. The inspection device according to claim 1, wherein
the controller acquires a current value of current flowing through the predetermined position instead of the voltage value at the predetermined position, and
the controller is configured to detect the abnormality of the inspection target based on data of the current value of the current flowing through the predetermined position instead of data of the voltage value at the predetermined position.

14. An inspection method executed by an inspection device for an inspection target, the inspection device comprising a power supply circuit including a power switch that switches a power supply state to the inspection target and a reception circuit that receives a signal from the inspection target, the inspection method comprising:
switching the power switch from an off-state to an on-state;
acquiring a voltage value at a predetermined position of the power supply circuit or the reception circuit for a predetermined time from a time when the power switch is switched from the off-state to the on-state;
storing the voltage value in a memory; and
detecting an abnormality of the inspection target based on data of the voltage value stored in the memory.
